(19) United States
(12) Patent Application Publication
(10) Pub. No.: US 2004/0239535 A1
(43) Pub. Date: Dec. 2, 2004

(54) Self-calibrating dielectric property-based switch

(75) Inventors: Thomas J. Chadwell, San Antonio, TX (US); David C. Sudolcan, Atascosa, TX (US)

Correspondence Address: LAW OFFICES OF CHRISTOPHER L. MAKAY, 1634 Milam Building, 115 East Travis Street, San Antonio, TX, 78205, US

(73) Assignee: LANCER PARTNERSHIP, LTD.

(21) Appl. No.: 10/449,294

(22) Filed: May 29, 2003

(51) Int. Cl. H03M 11/00; H03K 17/94

(52) U.S. Cl. 341/34

(57) ABSTRACT

A self-calibrating touch sensor generally includes a dielectric switch pad in electrical communication with a controller. A forcing function waveform is delivered to the dielectric switch pad. The step response waveform of the dielectric switch pad is then monitored by the controller to detect changes in the dielectric properties of the dielectric switch pad. Upon startup of a system in which the self-calibrating touch sensor is embedded or upon detection of an event indicative of a persistent change in the dielectric environment about the dielectric touch pad, the controller processes the step response waveform to determine the time constant of the circuit comprising the dielectric switch pad. The determined time constant is stored as baseline value by the controller. The controller then monitors the step response waveform for temporary changes from the stored value, indicative of a key press event.

### FIELD OF THE INVENTION

The present invention relates to electrical switches. More particularly, the invention relates to a dielectric property-based switch with self-calibrating capabilities.

### BACKGROUND OF THE INVENTION

Almost all point-of-sale systems comprise one or more keypad-type switches for user input. Typically, tactile mini-switches or membrane switches are utilized in such applications. As is known to those of ordinary skill in the art, these types of switches simply toggle between an open circuit and a closed circuit and thus are readily interfaced with digital control systems. Unfortunately, in many applications (and especially in applications for the food and beverage service industry) these switches suffer problems of reliability. For example, both switches comprise moving parts subject to failure with wear and/or contamination with corrosive syrups or the like. Additionally, tactile mini-switches are relatively costly among switches.

As a result of the foregoing reliability problems, other switches have been proposed for use in various applications. For example, dielectric property-based switches such as capacitive switches, charge transfer switches and RF switches may be implemented for the elimination of many of the reliability issues associated with conventional on-off type switches. In general, dielectric property-based switches comprise no moving parts and, as a result, such switches are far less likely to sustain physical damage and infusion of corrosive food products. Unfortunately, however, such switches have been generally been avoided in the food and beverage industry because they are analog devices. As such, implementation of a dielectric property-based switch requires the addition to an otherwise all-digital circuit of analog processing capabilities. Additionally, and adding to the cost of implementation, each implementation requires calibration during manufacture in order to adjust the switch to its electrical environment. As a result, the additional costs have heretofore generally outweighed the costs associated with failure of tactile mini-switches or membrane switches.

It is therefore an overriding object of the present invention to set forth an implementation of a dielectric property-based switch not requiring individual calibration during manufacturing. Additionally, it is an object of the present invention to set forth such an implementation that is also adapted to automatically adjust for changes in the electrical environment in which the switch is implemented, such as often occurs when a food product is splashed upon the dielectric property-based switch. Finally, it is an object of the present invention to set forth such an implementation that is readily utilized with a wider variety of system designs, thereby making the implementation economically available for incorporation into virtually any existing design.

### SUMMARY OF THE INVENTION

In accordance with the foregoing objects, the present invention—a self-calibrating touch sensor—generally comprises a dielectric switch pad in electrical communication with a controller. In operation, a forcing function waveform is produced by the controller and delivered through an input/output (“I/O”) port on the controller to the dielectric switch pad. The step response waveform of the dielectric switch pad is then monitored by the controller. In this manner, the controller is adapted to detect changes in the dielectric properties of the dielectric switch pad.

Upon startup of a system in which the self-calibrating touch sensor of the present invention is embedded or upon detection of an event indicative of a persistent change in the dielectric environment about the dielectric touch pad, the controller processes the step response waveform to determine the time constant of the circuit comprising the dielectric switch pad. The determined time constant, which is a direct measure of the dielectric properties of the dielectric switch pad, is stored as baseline value by the controller in any suitable memory device, such as random access memory (“RAM”) or flash electrically erasable programmable read only memory (“EEPROM”) or the like, which may be on-chip or off. The controller then enters an operational loop during each cycle of which the controller monitors the step response waveform for temporary changes from the stored value in the step response. Detection of a temporary change in the dielectric properties of the dielectric switch pad, such as will occur upon touching of the dielectric switch pad by a person's finger, results in processing of the key press according to the particular host system.

Finally, many other features, objects and advantages of the present invention will be apparent to those of ordinary skill in the relevant arts, especially in light of the foregoing discussions and the following drawings, exemplary detailed description and appended claims.

### BRIEF DESCRIPTION OF THE DRAWINGS

Although the scope of the present invention is much broader than any particular embodiment, a detailed description of the preferred embodiment follows together with illustrative figures, wherein like reference numerals refer to like components, and wherein:

FIG. 1 shows, in a functional block diagram, the preferred embodiment of the self-calibrating dielectric property-based switch of the present invention;

FIG. 2 shows, in a flowchart, the preferred method of operation of the switch of FIG. 1;

FIG. 3A shows, in a signal waveform, a representation of a forcing function utilized to drive the dielectric switch pad of the switch of FIG. 1;

FIG. 3B shows, in a signal waveform, a representation of the step response function of the dielectric switch pad of the switch of FIG. 1 under normal operating conditions;

FIG. 3C shows, in a signal waveform, a representation of the step response function of the dielectric switch pad of the switch of FIG. 1 under changing operating conditions; and

FIG. 4 shows, in a functional block diagram, an alternative embodiment of the self-calibrating dielectric property-based switch of the present invention.

### DETAILED DESCRIPTION OF THE PREFERRED EMBODIMENT

Although those of ordinary skill in the art will readily recognize many alternative embodiments, especially in light of the illustrations provided herein, this detailed description is exemplary of the preferred embodiment of the present invention, the scope of which is limited only by the claims appended hereto.

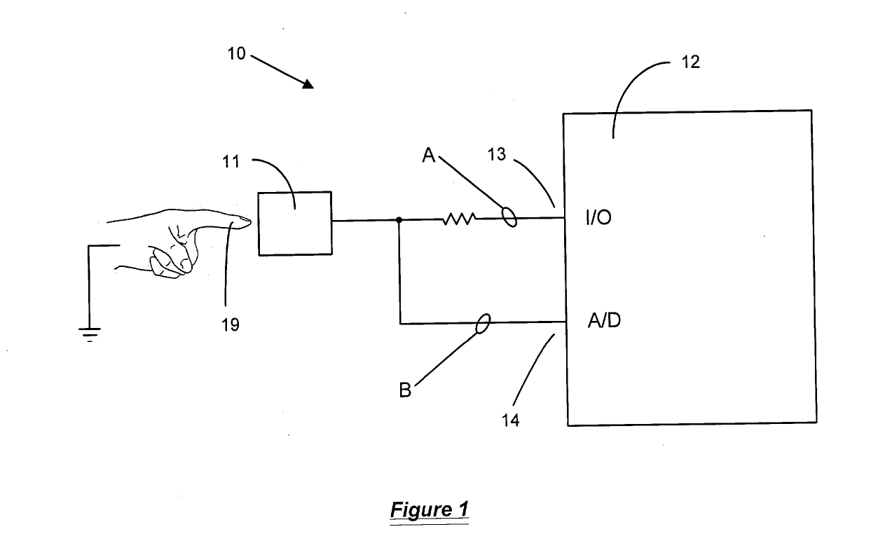

Referring now to FIG. 1 in particular, the self-calibrating dielectric switch 10 of the present invention is shown to generally comprise a dielectric switch pad 11, which may be capacitive, charge transfer, RF or any other substantial equivalent, in electrical communication with a controller 12. In operation, a forcing function waveform A is produced by the controller 12 and delivered through an input/output (“I/O”) port 13 on the controller 12 to the dielectric switch pad 11. The step response waveform B of the dielectric switch pad 11 is then monitored through an analog-to digital (“A/D”) input 14 by the controller 12. In this manner, the controller 12 is adapted to detect changes in the dielectric properties of the dielectric switch pad 11.

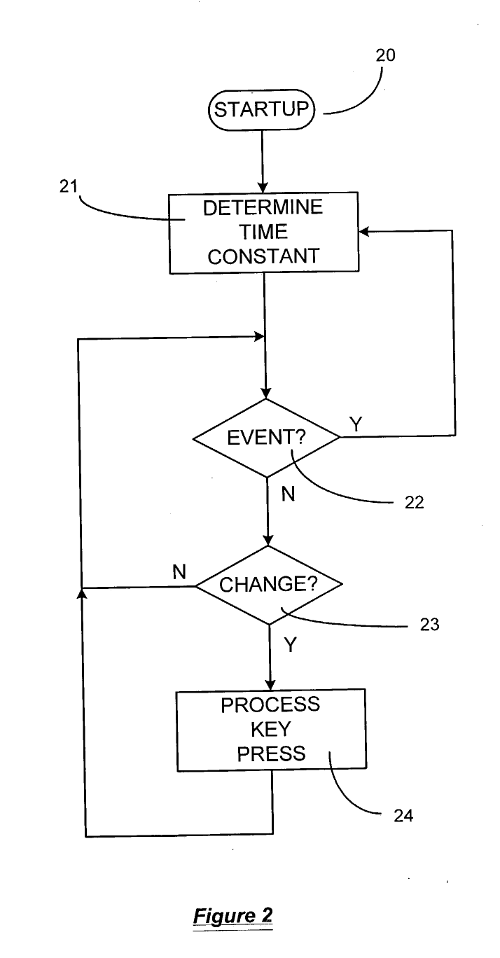

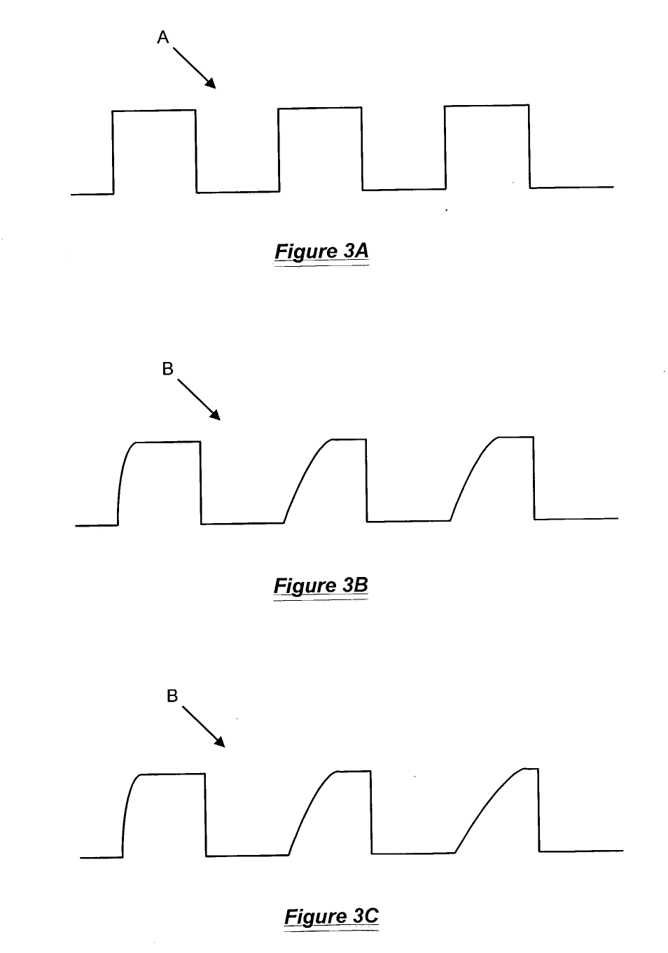

As shown in FIGS. 2 and 3, upon startup (step 20) of a system in which the self-calibrating dielectric switch 10 of the present invention is embedded, the controller 12 processes the step response waveform B to determine the time constant of the circuit comprising the dielectric switch pad 11 (step 21). The determined time constant, which is a direct measure of the dielectric properties of the dielectric switch pad 11, is stored as baseline value by the controller 12 in any suitable memory device, such as random access memory (“RAM”) or flash electrically erasable programmable read only memory (“EEPROM”) or the like (not shown), which may be on-chip or off. The controller 12 then enters an operational loop during each cycle of which the controller 12 monitors the host system for events indicative of a permanent or semi-permanent change from the stored value in the dielectric properties of the dielectric switch pad 11 (step 22) and monitors the step response waveform B for temporary changes from the stored value in the step response (step 23). Detection of an event indicative of a permanent or semi-permanent change (step 22) such as, for example, an alarm generated upon exceeding a predetermined maximum beverage pour time, results in re-determination (step 21 repeated) of the time constant of the dielectric switch pad 11. Detection of a temporary change in the dielectric properties of the dielectric switch pad 11, such as will occur upon touching of the dielectric switch pad 11 by a person's finger 19, results in processing of the key press (step 24) according to the particular host system. The operational loop then continues as shown in the figure.

As particularly shown in FIG. 3A, the dielectric switch pad 11 is preferably driven by a repeating step function generated by the controller 12. In this manner, as will be appreciated by those of ordinary skill in the art, the time constant of the step response waveforms—shown in FIGS. 3B and 3C, representative of the dielectric properties of the dielectric switch pad 11, may be readily obtained by measuring the rise time of each pulse of the step response waveforms B. While other driving functions may be implemented, Applicant has found that the described approach is readily implemented.

As particularly shown in FIGS. 3B and 3C, the rise time of each pulse of the step response waveforms B depends upon the dielectric constant of the dielectric switch pad 11, which in turn depends upon both the electrical environment in which the switch 10 of the present invention is implemented and the proximity to the dielectric switch pad 11 of other objects, such as a person's finger 19. As shown in the first pulse of FIG. 3B, the rise time in a given electrical environment can be expected to be generally the same pulse-to-pulse. Upon touching the dielectric switch pad 11 with a finger 19, however, the dielectric constant of the dielectric switch pad 11 changes as reflected in the increased rise times of the second and third pulses of FIG. 3B, which of course is readily detected by the controller 12.

As shown in FIG. 3C, however, the electrical environment about the dielectric switch pad 11 may undergo a permanent or semi-permanent change due to splashing of food product upon the switch or any number of other occurrences. In such a case, as reflected in the second pulse of FIG. 3C, the system may misinterpret the permanent or semi-permanent change as a key press. In the present invention, however, an alarm condition in the host system, such as may result detection of an over-pour of a beverage product, signals the controller 12 that a permanent or semi-permanent change has occurred, causing the controller 12 to recalibrate by measuring and storing the new baseline time constant of the step response waveform B. The step response waveform B is then monitored by the controller for deviations from the new baseline, as reflected in the third pulse of FIG. 3C, as indicative of a key press.

While the foregoing description is exemplary of the preferred embodiment of the present invention, those of ordinary skill in the relevant arts will recognize the many variations, alterations, modifications, substitutions and the like as are readily possible, especially in light of this description, the accompanying drawings and claims drawn thereto. For example, Applicant has found it convenient to implement the present invention utilizing a multifunction microcontroller such as the programmable system-on-chip microcontrollers commercially available from Cypress Microsystems of Bothell, Wash. under the trademark “PSOC.”Such microcontrollers include both analog and digital functionality, thereby providing full capability to measure the step response waveform B.

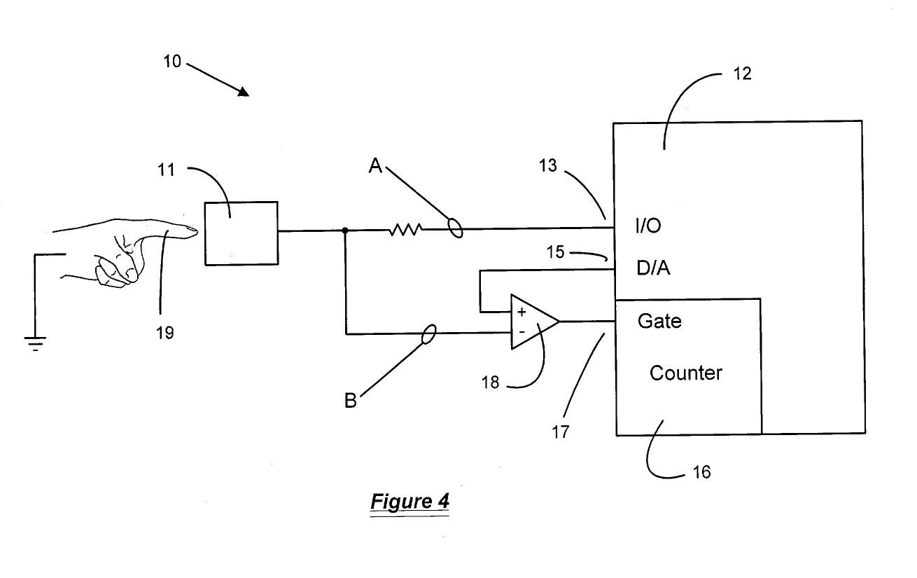

In the alternative, however, as shown in FIG. 4, a more traditional controller 12 may be utilized with the addition of a comparator 18 external the controller 12. In such an implementation, the step response waveform B is compared with a threshold voltage from the output 15 of a digital-to-analog (“D/A”) converter, which may be on-chip or off. The rise times of the step response pulses are then monitored by the controller 12 by feeding the output of the comparator 18 to an input gate 17 of a counter 16, which like the D/A converter may be on-chip or off. In any case, because the scope of the present invention is much broader than any particular embodiment, the foregoing detailed description should not be construed as a limitation of the scope of the present invention, which is limited only by the claims appended hereto.

What is claimed is:

1. A self-calibrating touch sensor, said touch sensor comprising:
a touch pad in electrical communication with a source of a first signal;
a circuit in electrical communication with said touch pad, said circuit being adapted to:
measure a characteristic of said first signal as electrically affected by said touch pad, said characteristic being indicative of the dielectric properties of said touch pad;
store a baseline value of said measured characteristic; and
detect changes in said measured characteristic with respect to said stored baseline value.

2. The touch sensor as recited in claim 1, wherein said touch pad comprises a capacitive pad.

3. The touch sensor as recited in claim 1, wherein said touch pad comprises a charge transfer pad.

4. The touch sensor as recited in claim 1, wherein said touch pad comprises a radio frequency pad.

5. The touch sensor as recited in claim 1, wherein said circuit comprises a controller.

6. The touch sensor as recited in claim 5, wherein said first signal is generated by said controller.

7. The touch sensor as recited in claim 6, wherein said first signal is a repeating step function.

8. The touch sensor as recited in claim 7, wherein said characteristic of said first signal is the time constant of the step response of said touch pad to said first signal.

9. The touch sensor as recited in claim 6, wherein said controller comprises an analog-to-digital converter, said analog-to-digital converter being adapted to monitor said first signal as electrically affected by said touch pad.

10. The touch sensor as recited in claim 9, wherein said controller is adapted to electronically store said baseline value of said measured characteristic.

11. The touch sensor as recited in claim 10, wherein said controller is further adapted to compare values of said measured characteristic with said baseline value of said measured characteristic.

12. The touch sensor as recited in claim 11, wherein said circuit further comprises a comparator, said comparator being adapted to compare the voltage of said first signal as electrically affected by said touch pad with a reference voltage.

13. The touch sensor as recited in claim 12, wherein said controller is further adapted to determine the time, from a predetermined start time, required for the voltage of said first signal as electrically affected by said touch pad to exceed said reference voltage.

14. The touch sensor as recited in claim 13, wherein said controller is further adapted to detect changes in said required time.

15. The touch sensor as recited in claim 11, wherein said controller is further adapted to detect changes in said dielectric properties of said touch pad based upon said comparison of said values of said measured characteristic with said baseline value of said measured characteristic.

16. The touch sensor as recited in claim 15, wherein said controller is further adapted to discriminate between said detected changes that are temporary and said detected changes that are persistent.

17. The touch sensor as recited in claim 16, wherein said controller is adapted to update said stored baseline value upon determination that said detected change is persistent.
